(19) United States
(12) Patent Application Publication
(10) Pub. No.: US 2011/0277804 A1
(43) Pub. Date: Nov. 17, 2011

(54) Power Generation

(76) Inventors: Ardeshir Eftekharzadeh, (US); Muhammad Mumtaz Qazilbash, (US)

(21) Appl. No.: 12/780,902

(22) Filed: May 16, 2010

(51) Int. Cl. H01L 31/04

(52) U.S. Cl. 136/243; 257/E31.001

(57) ABSTRACT

A novel device as well as a process for generating electric power from light is disclosed. This power generator comprises a material whose electric or magnetic dipole moment changes when the material absorbs light. The device further comprises mechanisms for blocking light from coming in and removing the block and control units for activating mechanisms that allow and block the light, in time for temperature of the aforementioned special material to reach a predetermined temperature. The afore-mentioned device may also comprise a voltage supply and control units for changing the output voltage of the voltage supply, the said voltage supply applies voltages to the said material.

### FIELD OF THE INVENTION

The present invention pertains generally to electrical power generation, and more particularly to a device and method and all embodiments thereof, for the transfor-mation of solar power to electricity.

### BACKGROUND OF THE INVENTION

Here a review of the existing technology is presented, to set the stage for the new invention.

It is now commonly believed that the widespread use of fossil fuels to produce energy has had a detrimental effect on the earth's climate and can have far reaching consequences for the wellbeing of mankind in the near and far future. Thus, it has become evident that development of technologies that can extract energy from renew-able resources (solar, wind, biomass, etc.), sometimes called green energy resources, is of paramount importance. Every year, the sun provides us with abundant energy, hence it has been several decades that solar power has been considered one of the most important sources of green energy.

Solar power generation has been realized through photo-voltaic cells and using steam and Stirling engines.
Quite generally speaking there are two ways to accomplish the task of converting the energy in light to the energy in moving charges. One way is to employ an interaction of photons in light with single atoms, or molecules or electrons. The other is to em-ploy the collective effect of light on a solid, fluid, gas or plasma. One such collective effect is to increase the temperature of the medium, light is radiated upon. If the medium resembles a plasma, (e.g. electron free gas) the other collective effect is to create oscillation in the collection of charges by interactions of electromagnetic nature. The interaction of light with single molecules, atoms or electrons follows the laws of quantum mechanics and thereby the Fermi golden rule. As a result, the efficiency of utilizing such effects depends on the frequency of light. White light contains a broad range of frequencies but nevertheless only a fraction of its energy is radiated in each frequency band. By contrast if the medium's surface does not reflect light, and the medium is not transparent, all of the energy in light must be absorbed and converted to heat. This inescapable fact would allow utilization of all frequency components of the light from the infrared through the visible to the ultraviolet. This invention pertains to utilizing the energy in the light in all of its components to generate elec-tricity. In our invention we utilize a material that when is heated by light, a dipole moment of electromagnetic type associated with that material varies as a result of exposure to light. This effect causes an electric potential difference to be induced in, say, two leads or other electricity conducting parts held adjacent to the material. It is widely known that electricity and magnetism are really two sides of the same coin. For example it is generally accepted that a static electric field in one reference frame, will appear as a magnetic field to an observer that is moving with respect to that reference frame. Also, electric dipoles and magnetic dipoles create similar field configurations and one can replace one for the other and arrive at similar results. Hence, the term “dipole” must be given its broadest reasonable interpretation as to include either electric dipole or magnetic dipole or in the case that a multiplicity of dipoles are present any number of the present dipoles can be electric while the rest can be magnetic. Similarly the term “dipole moment” should be interpreted as to cover both an electric dipole moment and a magnetic dipole moment. The above interpretations are, therefore, within the scope of present disclosure.

### SUMMARY OF THE INVENTION

It is an object of this invention to provide a new and improved method and a new and improved device for converting solar energy to electricity. It is a further object of this invention to provide a new and improved method as well as a device that provides for the conversion of solar energy to electricity with a material whose dipole moment changes when light is shone on it. It is yet a further object of this invention to provide a new and improved device as well as a method for generating electricity by exposing one or more pieces whose dipole moments change when they are irradiated by light or sun light and then allow the electric potential difference thus induced between conducting objects in proximity to the active material to cause current flow in the conducting objects. Accordingly another object of this invention is to provide for several methods and devices and any embodiments thereof, wherein incident light shining on a piece of material causes its dipole moment to change and therefore a potential difference is induced between conducting materials, wherein the exposure of the aforementioned material to light is stopped afterwards and the charges are allowed to flow and the cycle of exposure and allowing for flow of charges, blocking the exposure and allowing the charges to flow again, is repeated as long as there is enough light to allow the aforementioned process and where the light can be solar light that is collected and guided on to the aforementioned material. It is a yet further object of this invention to disclose a device comprising a piece of material whose dipole moment changes as a result of light impinging upon the surface of the material, a first mechanism which can allow light from a source present to reach the surface of the aforementioned material and a second mechanism which after a predetermined time duration or as a result of predetermined circumstances blocks the light from the same source to reach the material, wherein the device comprises one or more electricity conducting parts that are close enough to the aforementioned material to be induced with electrical charges and thermometers and/or potentiometers that send signals representing either the temperature of the said material or the potential difference between two of the said electricity conducting parts to control units which trigger the first and second mechanisms based on the temperature and/or the aforementioned potential difference are below or above a low or high value respectively. A yet another object of this invention is to disclose new devices and methods wherein a material whose dipole moment can change as a result of being exposed to light, is periodically exposed to light for a duration of time and taken out of light and into darkness for another duration of time and wherein, in this device and in the process one or more parts made of electricity conducting material are periodically charged and discharged with electrical charges. Also another object of this invention is to disclose new devices and methods comprising a material whose dipole moment can change as a result of being exposed to light, also comprising a part to collect and guide solar light onto this material and a mechanism to allow the light to irradiate the material and another mechanism to block the light shining on this material, further comprising conducting wires, thermometers, ammeters and/or potentiometers, wherein the change in the dipole moment induces a potential difference in the conducting wires and the material is periodically exposed to light and after each limited duration of exposure, it is put in darkness for another limited duration of time during which an electric field is applied while the active material cools down.

### DESCRIPTION OF PRIOR ART

A few patents mention the utilization of heat for power generation, for example,

| | | |
|---|---|---|
| U.S. Pat. No. 4,647,836 | Olsen | (1987) |
| U.S. Pat. No. 6,528,898 | Ikura et. al. | (2003) |
| U.S. Pat. No. 5,644,184 | Kucherov | (1997) |

Our disclosure here makes clear that our claims are patentably distinguishable from any of these patents.

### BRIEF DESCRIPTION OF THE DRAWINGS

The invention will now be described in more detail, by way of example only, with reference to the accompanying drawings, in which:

FIG. 1 is a perspective view of one embodiment of the power generator according to this disclosure.

FIG. 2 is a perspective view of another embodiment of the power generator according to this invention, where more than one light sensitive material and element are utilized.

FIG. 3 is a view of yet another embodiment of power generator in which a material is utilized whose magnetic dipole changes as a result of absorption of light.

While the patent invention shall now be described with reference to the preferred embodiments shown in the drawings, it should be understood that the intention is not to limit the invention only to the particular embodiments shown but rather to cover all alterations, modifications and equivalent arrangements possible within the scope of appended claims.

In all aspects of the present invention, references to special material mean any material or device wherein the dipole moment changes after absorbing light.

### DETAILED DESCRIPTION OF PREFERRED EMBODIMENTS OF THE INVENTION

Here We provide a detailed description of certain preferred embodiments of our invention with respect to the drawings.

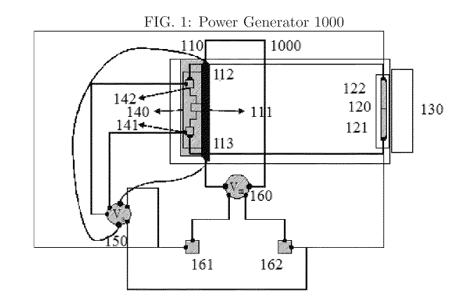

FIG. 1 shows one preferred embodiment of the disclosed invention. The power gener-ator 1000 comprises a part that collects and guides light of which the light collector 130 is a part. Part 120 comprises two mechanisms 121 and 122. In one embodiment they can be one and the same mechanism including but not limited to a diaphragm that opens (121) and closes (122). In another possible embodiment 120 can be a window with two sets of levers or gears wherein one set of levers or gears (121) can be activated to open the window, while another set (122) can be activated to close the same window. Other embodiments for part (120) are possible and are within the scope of this invention. The light sensitive part 111 is where the light is inci-dent upon. As a result of incidence of light the electric dipole moment of part 111 changes inducing charges on leads 112 and 113. In one embodiment the leads are positioned at the two ends of light sensitive material 111 in another embodiment the leads are transparent electrodes plates on two opposite surfaces facing the element 130, in yet another embodiment the leads are electrodes on any two other points or sides of the element 111. The embodiment disclosed in FIG. 1, also comprises thermometer 150 and controllers 141 and 142, where thermometer sends a signal to controllers representing the temperature of the light sensitive material 111. In the embodiment disclosed in FIG. 1, controller 141 would send a signal to mechanism 121 if the temperature of the material 111 is equal or lower than a predetermined value θ_{c}. The signal will cause the mechanism 121 to be activated which leads to light coming into the device and exposing the material 111. In one embodiment this can be achieved through opening a diaphragm or a window or using LCD devices that become transparent to polarized light as a result of application of electric voltage. Other embodiments are possible and within the scope of our invention. Controller 142 receives the temperature signal from thermometer 140 and if the temperature is higher or equal to predetermined temperature θₕ, it sends a signal to element 122, causing it to block the light from entering the device. In one embodiment the two controllers 141 and 142 are two mechanisms implemented by the same element and hence a one controller device is within the scope of the present disclosure. Also, in another possible embodiment the two mechanisms 121 and 122 are implemented via the same element. Hence a one controller or a single light controlling mechanism is within the scope of this invention. Furthermore the embodiment disclosed in FIG. 1, comprises voltage supply 150 potentiometer 160 and controllers 161 and 162. Controllers 161 and 162 receive the signal representing the potential difference between leads 112 and 113 and send triggering signals to voltage supply 160. These signals cause additional voltage to be applied at the time that the voltage difference is at its minimum absolute value. The triggering mechanism can also be used for blocking and unblocking light. Thus a variation that uses the signals from voltmeter 160 instead of the thermometer 140 is within the scope of the present disclosure. To summarize, There are two overall control mechanisms one to control the voltage supply and one to control light admission into the device. There are also two overall schemes to accomplish these controls, either by using the thermometer or the volt-meter. We submit here that any combination of the two schemes can be used to implement any of the two control mechanisms.

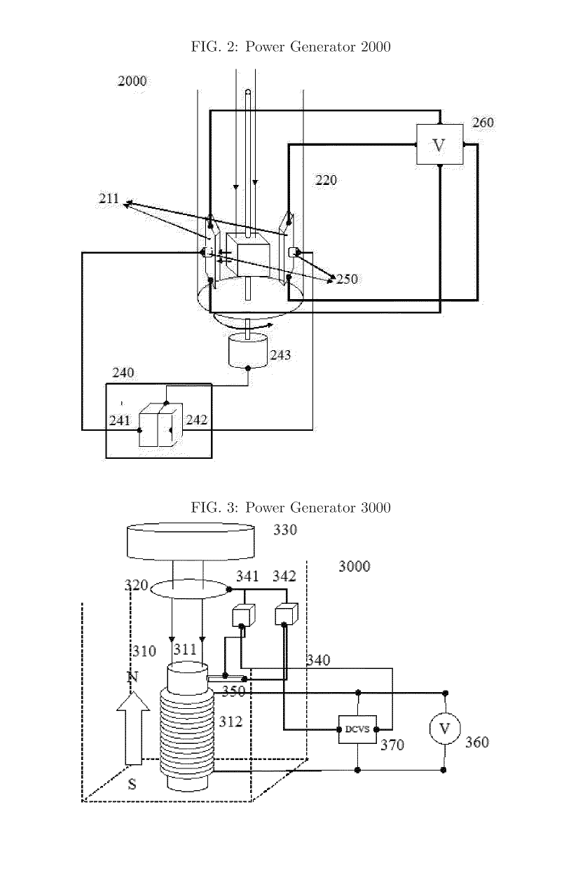

FIG. 2 discloses another possible embodiment of our invention. The power gener-ator 2000 as shown in FIG. 2, includes a part comprising element 220, that collects and guides light onto one of the elements 211. The combined elements 220 and 243, forms the mechanism that comprises first and second mechanisms which allow one of the elements 211 to be exposed to light while blocking the other and then switch between the elements. Thermometers 250 measure the temperature of elements 211 respectively and send signals to controllers 241 and 242, housed in element 240. The two controllers may be one and the same. When the temperature of one of the elements 211 is lower or equal to a predetermined temperature θ_{c} controller 241 send a signal to motor 243 which rotates the guiding element 220 and causes the light to be blocked from hitting one of the elements 211 and exposes the other. When the temperature of the other one is equal to greater a pre-determined θₕ the controller sends a different signal to the motor 243, causing light to be blocked from reaching one of the elements 211 and reach the first one. A power generator comprising any number of elements 211 is therefore covered by this disclosure. As a result of light shining on element 211 the electric dipole moment changes causing electric poten-tial and charge to be induced on the two electrodes attached to element 211. The voltage supply 260 applies a voltage to the elements and its voltage can be triggered by the potential difference between the leads exceeding a certain high threshold, in much the same manner as FIG. 1. Furthermore the leads or the voltage supply may be duplicated so that each element 211 has its own voltage supply and triggering mechanisms. All the above variations must be considered to fall within the scope of the present disclosure. FIG. 3 depicts the power generator 3000 as yet another embodiment of our present invention. The power generator 3000 comprises element 330 which is part of the system that collects and directs light onto the element 311 whose magnetic dipole changes as a result of exposure to light. Thermometer 350 measures temperature of the element 311 and sends signals to controllers 341 and 342. Controller 341 receives the signal from thermometer 350 and if the temperature is less than or equal to a predetermined temperature θ_{c} sends a signal to mechanism 320, or a certain part of it which causes the mechanism 320 to allow light to expose 311. Controller 342 receives temperature signal from thermometer 350 and if the temperature is equal or greater than a predetermined temperature θₕ sends a signal that activates the mechanism 320 or a certain part of it which blocks the light from reaching material 311. A variation of the aforementioned embodiment comprising two distinct mechanisms one for allowing and one for blocking the light is within the scope of this disclosure. A voltmeter or potentiometer 360 measures the voltage in the conducting element 312 which is induced as a result of change in the magnetic dipole of element 311. The magnetic dipole moment may be directed in the direc-tion shown. A variation on the above disclosure where the controllers 341 and 342 receive a signal from the voltmeter 360 rather than thermometer 350 is within the scope of this disclosure. Also within the scope is a variation where multiple elements identical to 311 are present and after that light ceases to expose one, it is redirected to expose another one. To enhance efficiency, one may include the DC voltage supply 370 to generate a dc current at the same time or after the controller 342 blocks the light. The dc current may be reduced or completely turned off when the controller 341 causes the light to enter the device. The timing may be controlled by the same controllers (as suggested by the drawing) or by some other means. Also within the scope of present invention, one might apply the current to a second coil similar to coil 312 or the current may be applied to the same coil. Modifying the present invention such that it includes multiple coils and multiple elements for the purpose of improving efficiency is covered by our present disclosure as being obvious modifications of the present disclosure. In the above, elements 130 and 330 (a part 230 could be similarly added to FIG. 2) are for collecting light and guiding the collected light toward the light sensitive parts. This is accomplished via various ways. In One embodiment part 130 and 330, comprise a lens, or a collection of lenses, in another possible embodiment part 130 and 330, comprise one or more parabolic or spherical concave mirror, an-other possible embodiment for part 130 and the similar part 330, is a collection of flat mirrors where each one can be oriented in such a way that the net result of reflection of light from all such mirrors is collection of light and guiding it toward the light sensitive part. In yet another possible embodiment guiding of the collected light can be accomplished using fiber optics, light guides, wave guides, or light pipes.

### BENEFITS OF THE INVENTION

This invention is advantageous for generating electric power in a novel and hitherto unexplored process. It utilizes all wavelength components of the light. It does not use a steam or thermal engine and therefore it has added benefit of having lower maintenance and construction costs since it has fewer moving parts.

### Other Embodiments

From the foregoing description, it will thus be evident that the present invention provides a design for electric power generators. As various changes can be made in the above embodiments and operating methods without departing from the spirit or scope of the following claims, it is intended that all matter contained in the above description or shown in the accompanying drawings should be interpreted as illustrative and not in a limiting sense.

Variations or modifications to the design and construction of this invention, within the scope of the appended claims, may occur to those skilled in the art upon reviewing the disclosure herein. Such variations or modifications, if within the spirit of this invention, are intended to be encompassed within the scope of any claims to patent protection issuing upon this invention.

### CROSS REFERENCE TO DISCLOSURE DOCUMENT

The embodiments of the invention in which we claim an exclusive property or privilege are defined as follows:

1. An electric power generator, comprising: a first opaque container with a first aperture on a first surface of the container, one or more parts of a first type inside the container each one comprising a first material having a first surface, means for collecting and guiding light from a source outside the container onto the said first surface, where in the said first material the dipole moment changes when the said material is exposed to light, and means for exposing the material to light for a first duration of time, and means for ending the said exposure after the expiration of the said first exposure, and wherein each part of the first type further comprises a conducting circuit comprising two leads where a first electrical potential difference between the said two leads changes as a result of the variation of the dipole moment of the first material.

2. The electrical power generator as disclosed in claim 2, where the exposure of the first material by the light and the subsequent blocking of the light are repeated, for an n^{th} time interval and (n+1)^{th} time interval respectively wherein n can be any integer number.

3. The electrical power generator as disclosed in claim 2, further comprising one or more thermometers and one or more potentiometers, wherein there is one ther-mometer and one potentiometer corresponding to each one of the one or more parts of the first type, wherein thermometers measure the temperature of the first material in each part and generate one or more electric or mechanical signals representing the temperature of the first material, and potentiometers measure the potential differ-ence between the said two leads and generate a signal representing the first potential difference, a first control unit that receives the signal generated by each of the ther-mometers and when the temperature is equal or greater than a first predetermined high temperature, activates the said first mechanism thereby blocking the light from exposing the first material and a second control unit that also receives the temper-ature of the first material from the first thermometer and when the temperature is equal or less than a second predetermined low temperature activates the said second mechanism thereby removing the blockade set by the first mechanism and allowing the exposure of the first material to the light.

4. The electrical power generator as disclosed in claim 3 in which the first pre-determined high temperature is the temperature at which the absolute value of the potential difference between the leads reaches its maximum.

5. The electrical power generator as disclosed in claim 4, further comprising a volt-age supply capable of supplying varying voltages, a control switch receives the tem-perature from the said first thermometer and activates the third mechanism which causes the voltage supply to apply a first high voltage to the first material if the temperature is equal or higher than the first predetermined high temperature, and wherein the fourth control unit receives the temperature from the said first thermome-ter and activates the fourth mechanism which causes the voltage supply to apply a second low voltage to the first material if the temperature is equal or less than a second predetermined high temperature.

6. The electrical power generator as disclosed in claim 5, where the dipole moment is the electric dipole moment.

7. The electrical power generator as disclosed in claim 5, where the dipole moment is the magnetic dipole moment.

8. A process for generating electric power, comprising: exposing one or more parts of first type each comprising a first material to light, wherein the material's dipole moment changes when the said material is exposed to light, for a first duration of time after which the exposure to light is ended, and the said first part is kept for a second duration of time away from light and this process is repeated a number of times and wherein there are two or more leads in proximity of each of the first materials included in the parts of first type, wherein the electric potential difference between two of the said leads changes as a result of the change in the said dipole moment.

9. The process as disclosed in claim 8, further comprising a step for collecting light from a first source and guiding it onto one of the parts of the first type and a surface of the first material.

10. The process as disclosed in claim 9, further comprising measuring the tem-perature of the first material in one of the parts of the first type and starting the exposure of the first material in each of the parts of the first type when its tempera-ture is equal or lower than a second low temperature and stopping the said exposure when its temperature is equal or higher than a first high temperature.

11. The process as disclosed in claim 10, wherein, at or shortly after the time that the exposure of one of the parts of the first type is stopped, the exposure of another one is started.

12. The process as disclosed in claim 11, further comprising measuring the poten-tial difference between two of the said leads adjacent to the first material in one of the parts of the first type and starting the exposure of the first material in each of the parts of the first type when the said potential difference is equal or lower than a second low value and stopping the said exposure when the said potential difference is equal or higher than a first high value.

13. The process as disclosed in claim 12, wherein the dipole moment of the first material is its electric dipole moment.

14. the process as disclosed in claim 12, wherein the dipole moment of the first material is its magnetic dipole moment.
